(19) United States
(12) Patent Application Publication
(10) Pub. No.: US 2024/0231221 A9
(43) Pub. Date: Jul. 11, 2024

(54) FABRICATION OF NANOIMPRINT WORKING STAMPS WITH COMBINED PATTERNS FROM MULTIPLE MASTER STAMPS

(71) Applicant: GOOGLE LLC, Mountain View, CA (US)

(72) Inventors: Lu Tian, Palo Alto, CA (US); Wei Jin, Saratoga, CA (US); Thomas Mercier, Weston, FL (US)

(21) Appl. No.: 18/489,404

(22) Filed: Oct. 18, 2023

Related U.S. Application Data
(60) Provisional application No. 63/417,721, filed on Oct. 20, 2022.

(51) Int. Cl. G03F 7/00; G02B 6/34; G02B 27/01; G03F 7/40

(52) U.S. Cl. CPC G03F 7/0002; G02B 6/34; G02B 27/0172; G03F 7/0005; G03F 7/0007; G03F 7/40; G02B 2027/0178

(57) ABSTRACT

A method for fabricating a working stamp for forming surface gratings in a waveguide workpiece includes performing a series of step lithography processes using a series of master stamps so as to form a working stamp having a first surface having a plurality of surface gratings formed therein. Each step lithography process includes pressing a master stamp of the series of master stamps into a material layer of a working stamp workpiece at a corresponding region of the material layer, the master stamp having a plurality of surface grating patterns formed thereon. Each step lithography process further includes applying ultraviolet light to the corresponding region to locally cure the material layer at the corresponding region and detaching the master stamp from the material of the working stamp after applying the ultraviolet light.

### CROSS-REFERENCE TO RELATED APPLICATIONS

The present application claims priority to U.S. Provisional Application No. 63/417,721, entitled “FABRICATION OF NANOIMPRINT WORKING STAMPS WITH COMBINED PATTERNS FROM MULTIPLE MASTER STAMPS” and filed on Oct. 20, 2022, the entirety of which is incorporated by reference herein.

### BACKGROUND

Head-mounted devices (HMDs), heads-up displays (HUDs) and other near-eye display systems often employ waveguides that utilize surface gratings or holographic gratings for various light manipulation purposes, such as the incoupling of display light into the waveguide or the outcoupling of display light from the waveguide toward the direction of a user's eye. A common approach to fabrication of a waveguide with surface gratings relies on the use of a working stamp that has the negative, or inverse, pattern of the intended pattern of the surface gratings. The working stamp is pressed into the appropriate location on the surface of a waveguide workpiece to form the corresponding surface grating pattern at that surface of the waveguide workpiece. After withdrawing the working stamp from the waveguide workpiece, a curing process then may be applied to the area in which the surface gratings were formed so as to cure and harden the surface gratings.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIGS. 1 and 2 are block diagrams that together illustrate a method for fabrication of a working stamp for forming surface gratings in a waveguide workpiece using a step nano-imprint lithography process in accordance with implementations.

FIG. 3 is a diagram illustrating top plan views of a series of master stamps and a resulting working stamp using the step nano-imprint lithography process of FIGS. 1 and 2 in accordance with implementations.

FIGS. 4 and 5 are block diagrams that together illustrate a method for fabrication of a working stamp for forming surface gratings in a waveguide workpiece using an overlay nano-imprint lithography process in accordance with implementations.

FIG. 6 is a diagram illustrating top plan views of a series of master stamps and a resulting working stamp using the overlay nano-imprint lithography process of FIGS. 4 and 5 in accordance with implementations.

FIG. 7 is a block diagram illustrating a method for fabrication of a working stamp for forming surface gratings in a waveguide workpiece using a hybrid nano-imprint lithography process in accordance with implementations.

FIG. 8 is a diagram illustrating a method for fabrication of surface gratings in a waveguide workpiece using a working stamp in accordance with implementations.

FIG. 9 illustrates a perspective rear view of AR glasses having at least one waveguide with slanted gratings in accordance with implementations.

### DETAILED DESCRIPTION

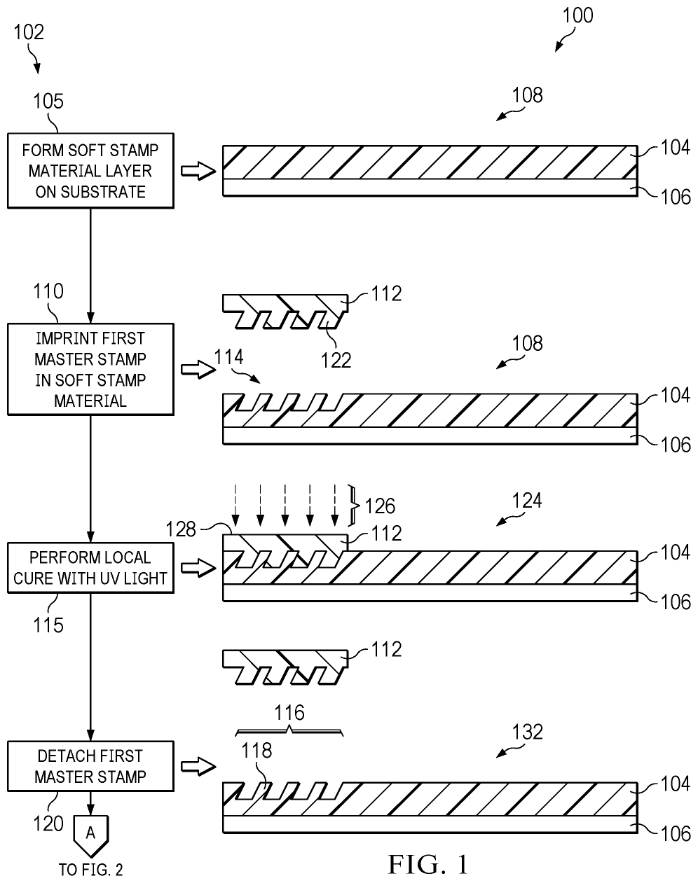

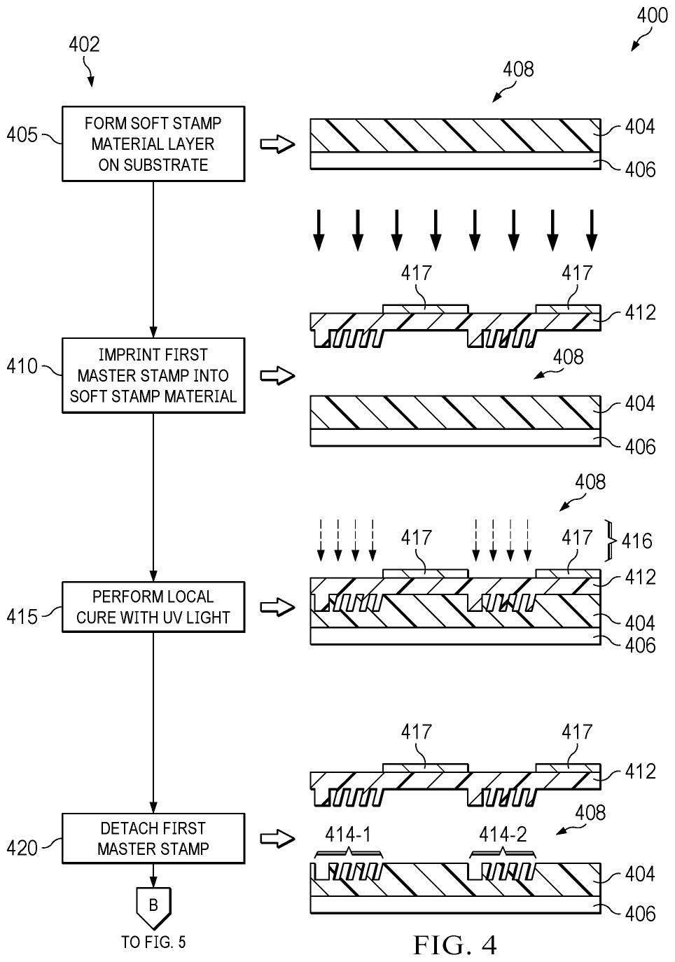

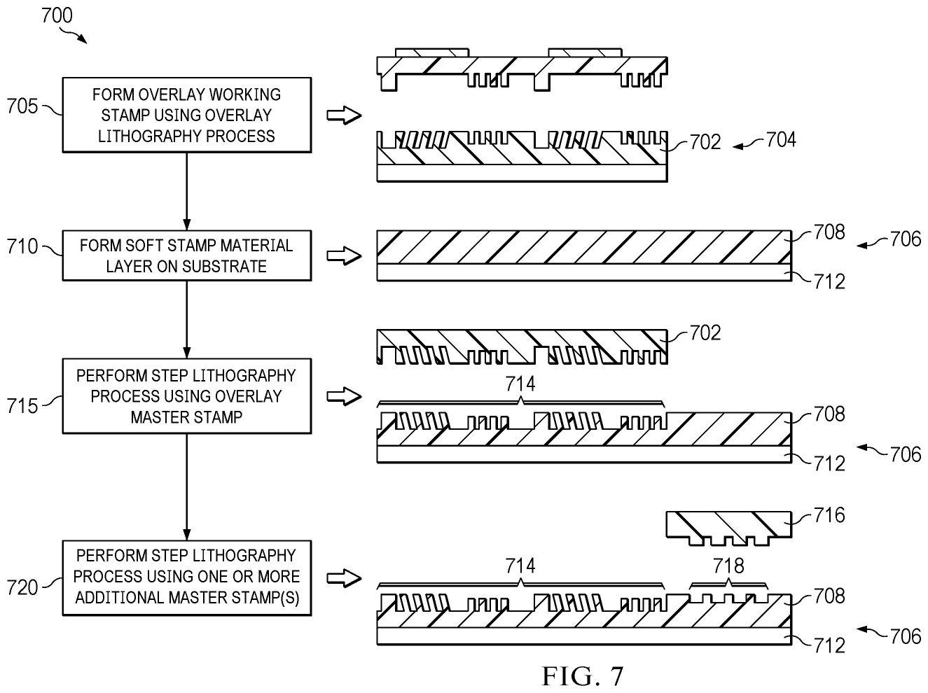

Conventional nanoimprint processes for forming different surface gratings at different locations of a waveguide workpiece or similar larger optical workpiece typically require all grating patterns be implemented in a single master wafer, the patterns then imprinted from the single master wafer to a set of working stamps, and then transferring the patterns from the working stamps to replication wafers. This complexity in the conventional master-stamp-replication process increases with designs that require various patterns with large structural or dimensional differences to be produced on the same master wafer. To illustrate, it is considerably more difficult and expensive to fabricate a single master with both slanted gratings and a large-area two-dimensional (2D) grating with different area grating depths than to fabricate both a master with single-depth slanted grating patterns and another master with a 2D grating pattern with different depths. Accordingly, disclosed herein are techniques for combining the gratings patterns from multiple masters by imprinting them onto a single working stamp. In particular, these approaches include: (1) a step nanoimprint lithography process using a series of step master stamps (see FIGS. 1-3), (2) an overlay nanoimprint lithography process using a series of overlay master stamps (see FIGS. 4-6), and (3) a hybrid process that combines (1) and (2) (see FIG. 7). These approaches provide flexibility in producing working stamps with complicated patterns. Moreover, the processes can be tuned and better optimized for one type of pattern or one group of similar patterns, and thereby facilitating the fabrication of master stamps with better quality, higher yield, and shorter turnaround times.

Used herein are various position-based or orientation-based terms, such as “vertical”, “horizontal”, “top”, “bottom”, and the like. It will be appreciated that these terms are used merely with reference to the orientation of the view of the corresponding figure, and are not intended to specifically describe a particular orientation with respect to a gravitational reference unless otherwise noted.

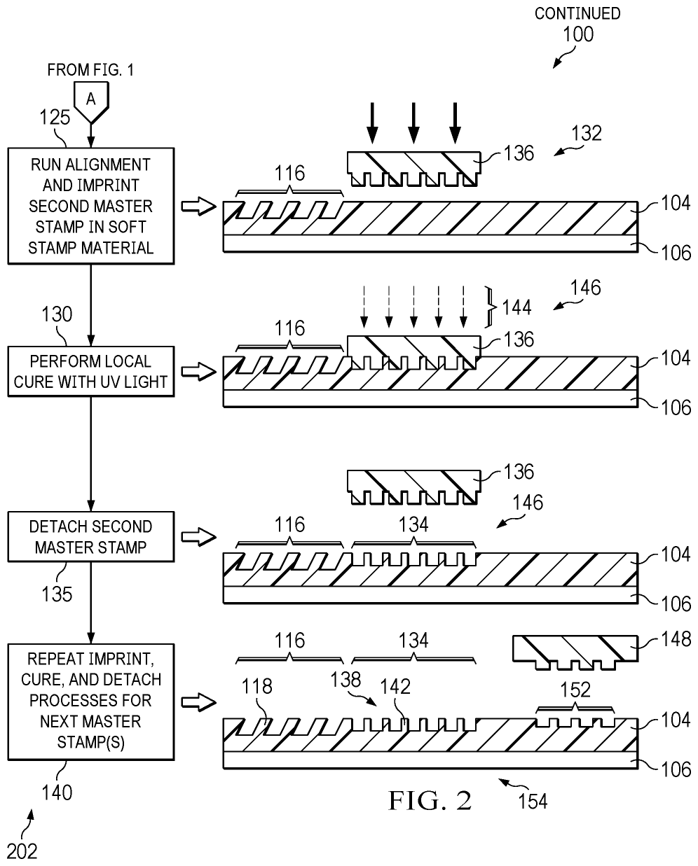

FIGS. 1 and 2 together illustrate an initial phase 102 (FIG. 1) and final phase 202 (FIG. 2) of a method 100 for fabricating a working stamp for fabrication of different gratings of different patterns in a waveguide workpiece using a step nanoimprint lithography process in accordance with some embodiments. The initial phase 102 begins at block 105 with the formation of a soft stamp layer 104 overlying a suitable substrate 106, such as a quartz or silicon substrate, resulting in a stamp workpiece 108. The soft stamp layer 104 may be composed of any of a variety of suitable soft materials that subsequently can be cured or otherwise transformed into a harder state, such as an uncured polymer. At block 110, a first step lithography process is initiated by aligning a first master stamp 112 with a corresponding first location 114 of the working stamp workpiece 108, such as by using alignment marks or other similar alignment tools, and then imprinting a first pattern 116 from the first master stamp 112 into the soft stamp layer 104 by pressing the first master stamp 112 into the soft stamp layer 104 at the corresponding aligned first location 114. In the illustrated example, the first master stamp 112 is configured to form slanted gratings 118 in the working stamp workpiece by virtue of negative, or complementary, slanted gratings 122 in the first master stamp 112.

At block 115, a local ultraviolet (UV) cure process is performed on the resulting workpiece 124 by applying UV light 126 to the region underlying the first master stamp 112 while the first master stamp 112 remains embedded in the soft stamp layer 104. In implementations, this is achieved by forming the first master stamp 112 using a polymer or other stamp material that is transparent or semi-transparent to UV light, thereby allowing the UV light 126 applied to a top side 128 of the first master stamp 112 to transmit through the first master stamp 112 to the underlying material of the soft stamp layer 104. A mask overlying the workpiece 124 and with an opening aligned with the first location 114 may be used to prevent UV light from prematurely curing other regions of the soft stamp layer 104. At block 120, the first master stamp 112 is detached from the soft stamp layer 104, resulting in a workpiece 132 that has the first pattern 116 of slanted gratings 118 formed in the first location 114 with locally cured material of the soft stamp layer 104.

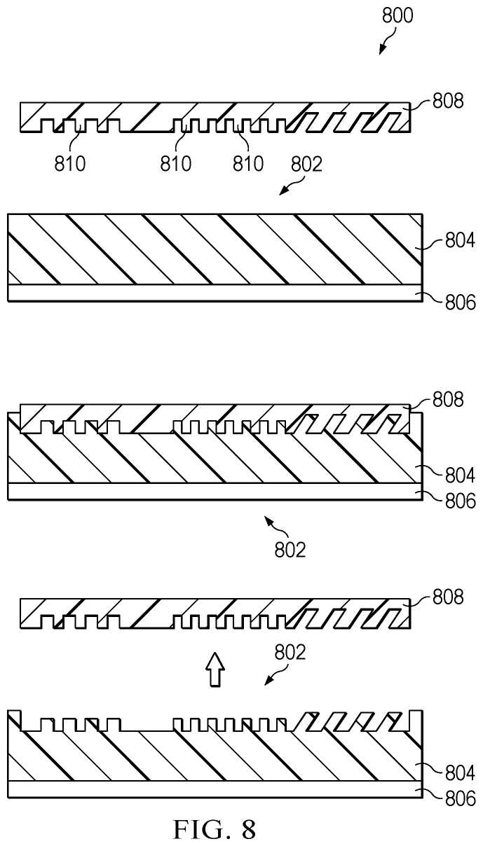

Referring to FIG. 2, the method 100 continues at block 125, in which a second step lithography process is initiated by aligning and imprinting a second pattern 134 from a second master stamp 136, such that the second master stamp 136 is pressed into the stamp layer 104 at a corresponding aligned second location 138. In the illustrated example, the second master stamp 136 is configured to form binary gratings 142 in the workpiece. At block 135, a local UV cure process is performed by applying UV light 144 to the region underlying the second master stamp through the second master stamp 136, which is composed of material that is transparent or semi-transparent to UV light so as to permit the UV light 144 to transmit through the second master stamp 136 so as to impinge on the underlying material of the soft stamp layer 104. As with the first local cure process, a mask may be utilized to ensure other regions of the soft stamp layer 104 are not inadvertently cured at the same time. At block 135, the second master stamp 136 is detached from the working stamp workpiece 132, resulting in a workpiece 146 having both the pattern 116 of slanted gratings 118 at the first aligned location 114 and the pattern 134 of binary gratings 142 at the second aligned location 138. As represented by block 140, this align-imprint-cure-detach process may be repeated for one or more additional master stamps (e.g., third master stamp 148) to form corresponding surface grating features/patterns at corresponding locations (e.g., aligned location 152), resulting in a working stamp workpiece 154 having different patterns of gratings in different regions formed via this step-wise process. The working stamp workpiece 154 then may be subjected to one or more wide-area UV cure processes to further cure/harden the entire stamp layer 104, and the resulting cured stamp layer may then be separated from the substrate 106, resulting in a working stamp (see, e.g., working stamp 812, FIG. 8).

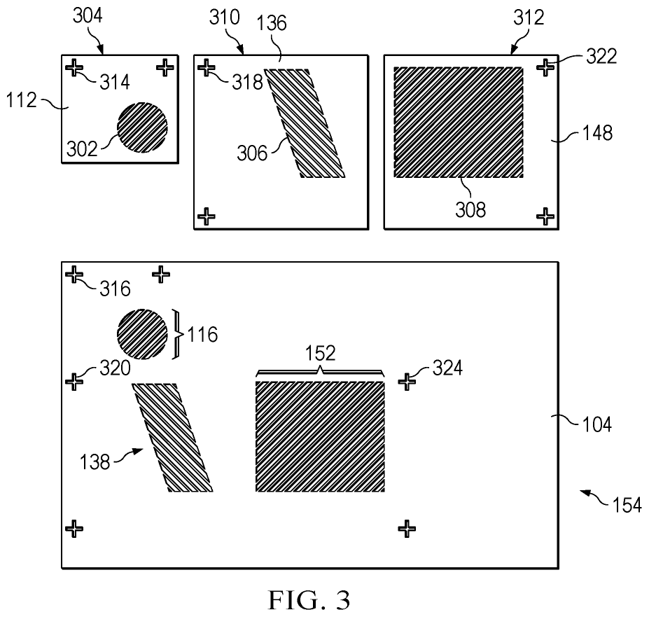

FIG. 3 illustrates top views of the first master stamp 112, the second master stamp 136, the third master stamp 148, and the working stamp 154 in accordance with implementations. As illustrated, each of the master stamps 112, 136, 148 may be composed of substantially UV-transparent material implementing the features that are pressed into the soft stamp layer 104 so as to form the conformal surface grating features, as well as an overlying mask layer that is configured to prevent transmission of UV light except in the region in which the stamp features are formed. For example, the master stamp 112 has an aperture 302 formed in a corresponding mask layer 304 so as to permit transmission of UV light through the master stamp 112 so as to locally cure the material of the soft stamp layer 104 underlying the aperture 302. The master stamps 136 and 148 likewise have respective apertures 306 and 308 in their respective mask layers 310 and 312 to facilitate UV curing local to the regions in which corresponding grating patterns are formed when the corresponding master stamp is pressed into the soft stamp layer 104. The top view of the working stamp workpiece 154 in FIG. 3 illustrates the patterns 116, 134, and 152 of surface grating features formed by the method 100 using the master stamps 112, 136, and 148 as illustrated in FIGS. 1-3. These top views also illustrate the use of alignment marks (e.g., the depicted crosses) to facilitate alignment of the master stamps to the soft stamp layer 104 during the fabrication of the working stamp workpiece 154. For example, alignment mark 314 of the master stamp 112 is aligned with alignment mark 316 of the soft stamp layer 104, alignment mark 318 of the master stamp 136 is aligned with alignment mark 320 of the soft stamp layer 104, and alignment mark 322 of the master stamp 148 is aligned with alignment mark 324 of the soft stamp layer 104.

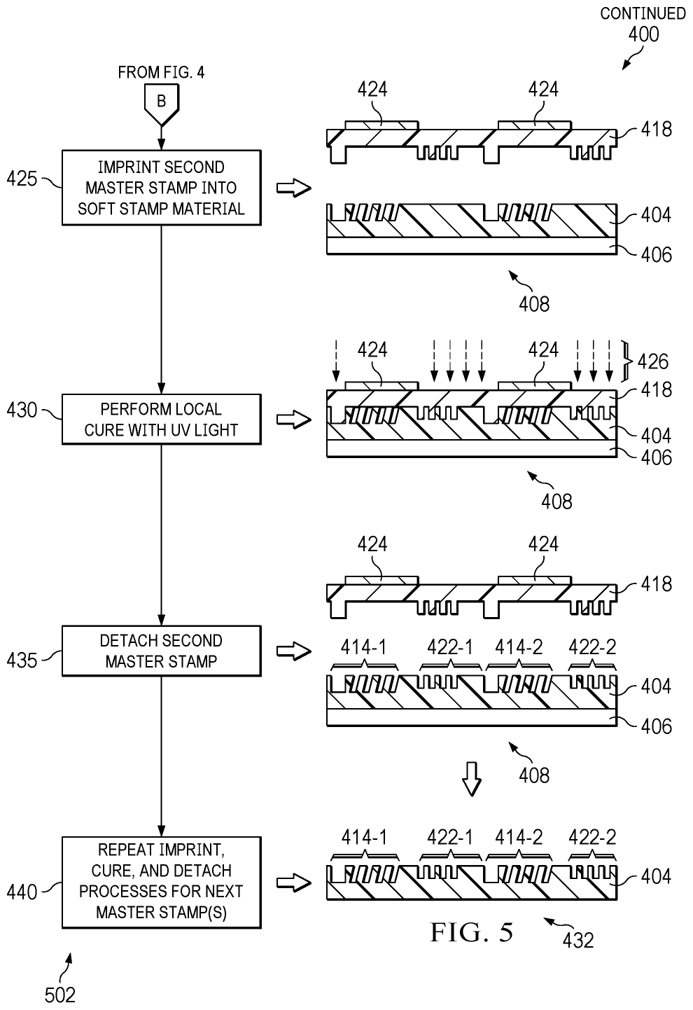

FIGS. 4 and 5 below illustrates an initial phase 402 (FIG. 4) and final phase 502 (FIG. 5) of a method 400 for fabricating a working stamp for fabrication of different gratings of different patterns in a waveguide workpiece using an overlay nanoimprint lithography process in accordance with some embodiments. The initial phase 402 initiates at block 405 with forming a soft stamp layer 404 (e.g., an uncured polymer) overlying a suitable substrate 406, such as a quartz or silicon substrate, of a stamp workpiece 408. At block 410, a first overlay lithography process is initiated by aligning a first master stamp 412 with the working stamp workpiece 408 (using alignment marks or other similar alignment tools) and then imprinting a set of patterns 414-1 and 414-2 from the first working stamp 412 by pressing the first working stamp 412 into the soft stamp layer 404. In the illustrated embodiment, the first master stamp 412 is configured to form slanted gratings in the working stamp workpiece 408. Moreover, in this process, the first master stamp 412 is dimensioned the same as the underlying working stamp workpiece 408 and is composed mainly of a material that is transparent or semi-transparent to UV light. However, unlike the step nano-imprint lithography technique of FIGS. 1-3 in which a local UV cure is performed by applying UV light only in a specific region of the working stamp workpiece, as described below with reference to block 415, in the overlay lithography process UV light is applied over the entire overlay master working stamp 412, and thus over the entire (or most) of the working stamp workpiece 408. Accordingly, to prevent the material from the soft stamp layer 404 from curing in locations that have not been patterned by the first master stamp 412, a coating 417 of a metal or other UV-opaque material is patterned on the backside of the first master stamp 412 to shield the unpatterned regions of the working stamp layer from being exposed to UV light. Accordingly, at block 415, a local ultraviolet (UV) cure process is performed by applying UV light 416 to the patterned regions of the soft stamp layer 404 underlying the first master stamp 412 through the first master stamp 412 (with the first master stamp 412 being transparent or semi-transparent to UV light) while the unpatterned regions are shielded from UV light by patterned coating 417, and thus remain uncured, by the metal/UV shielded regions of the first master stamp 412. At block 420, the first master stamp 412 is detached from the working stamp workpiece 408. Although FIGS. 4 and 5 illustrate an embodiment in which predeposited metal/UV-opaque material is used on the back surface to selectively block UV light during the curing process, in other embodiments a pre-patterned shutter for the UV light source instead can be used with each overlay master stamp 412 to provide for location-specific UV curing.

Turning to final phase 502 of FIG. 5, at block 425, a second overlay lithography process is initiated by aligning a second master stamp 418 with the working stamp workpiece 408 and then imprinting a set of second patterns 422-1 and 422-2 from the second master stamp 418 by pressing the second master stamp 418 into the soft stamp layer 404. In the illustrated implementation, the second master stamp 418 is configured to form binary gratings in the working stamp workpiece 408. As with the first master stamp 412, the second master stamp 418 is dimensioned the same as the underlying working stamp workpiece 408, is composed mainly of a material that is transparent or semi-transparent to UV light, and includes a patterned coating 424 of a metal or other UV-opaque material on the backside of the second master stamp 418 to shield the unpatterned regions of the soft stamp layer 404 from being exposed to UV light. Accordingly, at block 430, a local UV cure process is performed by applying UV light 426 to the patterned regions underlying the second master stamp 418 through the second master stamp 418 while the unpatterned regions are shielded from UV light, and thus remain uncured, by the metal/UV shielded regions of the second master stamp 418. At block 435, the second master stamp 418 is detached from the working stamp workpiece 408. As represented by block 440, this overlay-imprint-cure-detach process may be repeated for one or more additional overlay master stamps to form corresponding surface grating features/patterns at corresponding locations of the working stamp workpiece 408. After the final master stamp is removed, the soft stamp layer 404 may be subjected to a final curing process to complete the curing process and then separated from the substrate 406, resulting in a working stamp 432.

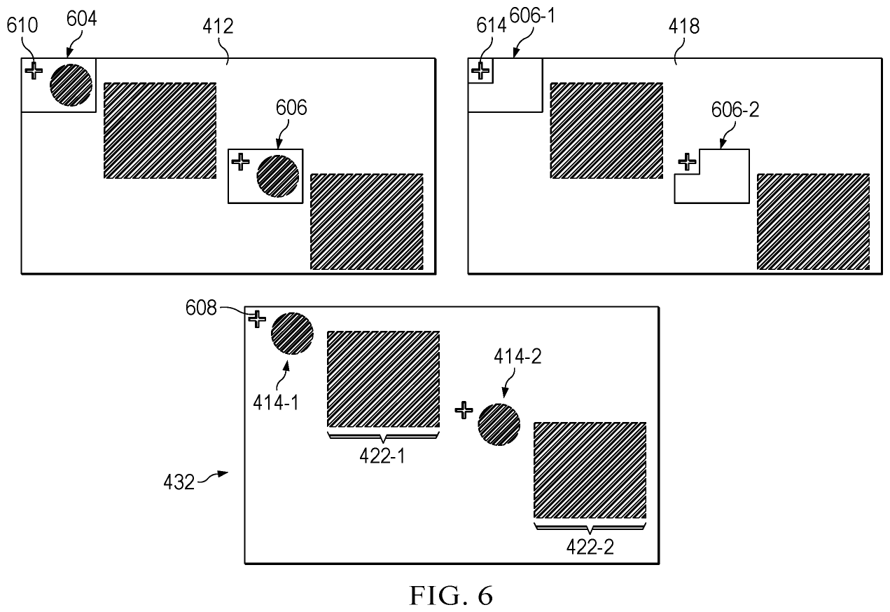

FIG. 6 illustrates the top views of the two master stamps 412 and 418 illustrated in FIGS. 4 and 5 and a top view of the resulting working stamp 432 formed through this process. As illustrated, the first master stamp 412 can include the overlying metal patterned coating 417 that completely coats the top surface of the first master stamp 412 with the exception of apertures 604, 606 in the regions corresponding to patterns 414-1 and 414-2 of surface gratings to be formed by the first master stamp 412 so as to permit transmission of UV light through these apertures so as to at least partially cure the underlying soft stamp material while the first master stamp 412 is in situ. In this example, the second master stamp 418 is the final overlying master stamp to be utilized for fabricating the working stamp 432, and thus rather than forming a complete overlying metal coat with apertures, the second master stamp 418 instead may the provide the metal patterned coating 424 in the form of two metal coat patches 606-1 and 606-2 dimensioned and aligned so as to cover the regions 604 and 606 so that the patterns 414-1 and 414-2 are not subjected to a second UV curing process during the UV curing process employed with the second master stamp 418, while the rest of the second master stamp 418 permits UV light transmission, and thus allowing local curing of the soft stamp layer 404 in the regions corresponding to patterns 422-1 and 422-2, as well as the rest of the soft stamp layer 404 with the exception of the two regions underlying the metal coat patches 606-1 and 606-2. Moreover, as shown in FIG. 6, alignment marks (e.g., alignment marks 608, 610, and 612) may be used to facilitate proper alignment of the overlying master stamps 412 and 418 to the workpiece.

FIG. 7 below illustrates a method 700 for fabricating a working stamp for fabrication of different gratings of different patterns in a waveguide workpiece using a hybrid process that utilizes both the step nanoimprint lithography process of FIGS. 1-3 and the overlay nanoimprint lithography process of FIGS. 4-6 in accordance with some embodiments. At block 705, the overlay lithography process as described above with reference to FIGS. 4-6 is used to fabricate a first working stamp 702 from a first working stamp workpiece 704. At block 710, a second working stamp workpiece 706 having a soft stamp layer 708 overlying a suitable substrate 712 is formed. At block 715, a first step lithography process is performed on the second working stamp workpiece 706 using the first working stamp to form a first set 714 of grating patterns in the second working stamp workpiece 706. At block 715, a second step lithography process as described above with reference to FIGS. 4-6 is performed on the second working stamp workpiece 706 using a separate master stamp 716 to form a second set 718 of grating patterns in the second working stamp workpiece 706. This process may be repeated for one or more other step master stamps, and the resulting second working stamp workpiece further processed (e.g., a final UV curing) to form a second working stamp that can then be used to imprint the resulting grating patterns in a waveguide workpiece or other workpiece.

FIG. 8 illustrates an example method 800 for forming surface gratings in a waveguide workpiece using a working stamp formed according to any of the step lithography process, overlay lithography process, or hybrid lithography process described above. As shown, a waveguide workpiece 802 composed of a soft waveguide material layer 804 formed on a stiff support carrier 806 is provided. A working stamp 808 (e.g., one embodiment of the working stamp 154, the working stamp 423, or 706) is oriented so that the surface gratings 810 (representing the negative, or inverse, gratings pattern to be formed in the waveguide workpiece 802) face the soft waveguide material layer 804 and are positioned overlying the region in which the gratings are to be formed. The working stamp 808 is coated with an anti-stick material and then pressed into the facing surface of the soft waveguide material layer 804, causing the soft waveguide material layer 804 to conform to the working stamp 808, and in particular, to form the indicated gratings in the soft waveguide material layer 804. The working stamp 808 is then removed from the waveguide material layer 804 and at least the impacted region of the waveguide material layer is cured to retain the gratings pattern, resulting in waveguide workpiece 812 having a patterned waveguide material layer 814. In some implementations, the waveguide material layer 804 can be partially cured while the working stamp 808 is in place so as to partially harden the waveguide material that forms the surface gratings and then the region is subjected to a second cure process to fully cure the region after the working stamp is withdrawn. In other embodiments, the working stamp 808 is withdrawn first and then a full cure process is performed. The patterned waveguide material layer 814 then may be separated from the carrier 806, resulting in a working stamp having the patterned surface gratings.

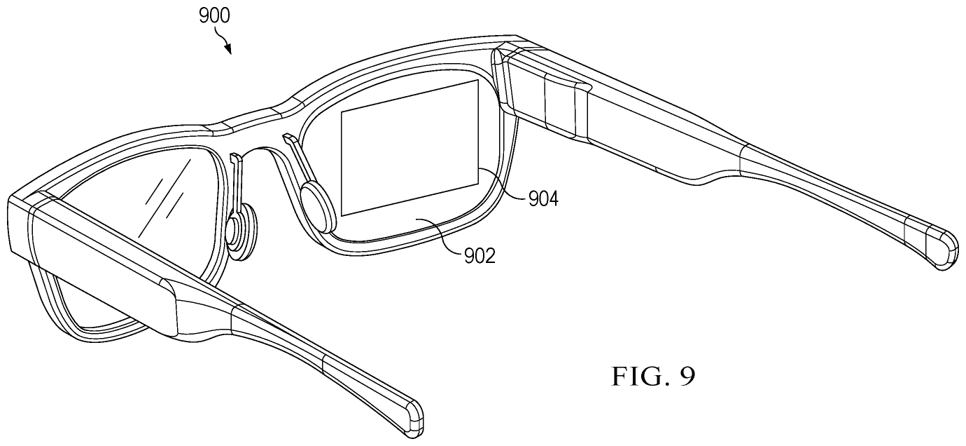

FIG. 9 illustrates a set of AR glasses implementing a waveguide having a variety of surface gratings formed via use of a working stamp formed via one or more of the processes described above. As shown, the AR glasses 900 include a set of lenses, including a lens 902 incorporating a waveguide 904. The waveguide 904 can incorporate surface gratings fabricated as described above, such as for an incoupler, an outcoupler, an exit pupil expander, or some other optical component of the waveguide.

In some embodiments, certain aspects of the techniques described above may be implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A method comprising:
performing a series of step lithography processes using a series of master stamps so as to form a working stamp having a first surface having a plurality of surface gratings formed therein, each step lithography process including:
pressing a master stamp of the series of master stamps into a material layer of a working stamp workpiece at a corresponding region of the material layer, the master stamp having a plurality of surface grating patterns formed thereon;
applying ultraviolet light to the corresponding region to locally cure the material layer at the corresponding region; and
detaching the master stamp from the material layer of the working stamp workpiece after applying the ultraviolet light.

2. The method of claim 1, wherein:
the master stamp is at least partially transparent to the ultraviolet light; and
applying ultraviolet light to the corresponding region comprises applying ultraviolet light to the corresponding region through the master stamp.

3. The method of claim 2, further comprising:
applying ultraviolet light to the material layer subsequent to performing the series of step lithography processes.

4. The method of claim 1, wherein each master stamp of the series of master stamps is configured to form a different pattern of surface gratings.

5. The method of claim 4, wherein each pattern of surface gratings differs by at least one of a size, a type, or an orientation.

6. The method of claim 1, wherein each working stamp is aligned to the corresponding region using at least one alignment mark on the working stamp and at least one alignment mark on the working stamp workpiece.

7. The method of claim 1, wherein the material that is at least partially transparent to ultraviolet light is composed of a polymer.

8. A waveguide fabricated according to the method of claim 1.

9. A set of augmented reality glasses utilizing a waveguide formed from the waveguide of claim 8.

10. A method comprising:
pressing a first side of a first master stamp into a material layer of a working stamp workpiece, the first side having a first plurality of surface grating patterns formed thereon and the first master stamp having an opposing second side with a patterned metal layer formed thereon, and a body of the first master stamp composed of a material that is at least partially transparent to ultraviolet light;
applying ultraviolet light to the second side of the first master stamp to selectively cure the material layer of the working stamp; and
detaching the first master stamp from the material of the working stamp workpiece after applying the ultraviolet light.

11. The method of claim 10, wherein the patterned metal layer includes apertures corresponding to locations of the surface grating patterns of the first plurality of surface grating patterns.

12. The method of claim 10, wherein pressing the first side of the first master stamp into the material layer includes aligning the first master stamp to the working stamp workpiece using at least one alignment mark on the first master stamp and at least one alignment mark on the working stamp workpiece.

13. The method of claim 10, further comprising:
pressing a first side of a second master stamp into the material layer of a working stamp workpiece following detaching the first master stamp, the first side of the second master stamp having a second plurality of surface grating patterns formed thereon and the second master stamp having an opposing second side with a patterned metal layer formed thereon, and a body of the second master stamp composed of a material that is at least partially transparent to ultraviolet light;
applying ultraviolet light to the second side of the second master stamp to selectively cure the material layer of the working stamp; and
detaching the second master stamp from the material of the working stamp workpiece after applying the ultraviolet light.

14. The method of claim 13, wherein pressing the first side of the first master stamp into the material layer includes aligning the first master stamp to the working stamp workpiece using at least one alignment mark on the first master stamp and at least one alignment mark on the working stamp workpiece.

15. The method of claim 13, wherein the patterned metal layer on the second side of the second master stamp includes a metal coating in regions in locations corresponding to regions of the first master stamp in which the first plurality of surface grating patterns is formed and is absent of a metal coating in regions of the second master stamp in which the second plurality of surface grating patterns is formed.

16. The method of claim 10, wherein the material that is at least partially transparent to ultraviolet light is composed of a polymer.

17. A waveguide fabricated according to the method of claim 10.

18. A set of augmented reality glasses having the waveguide of claim 17.
